(19) United States
(12) Patent Application Publication
(10) Pub. No.: US 2016/0233114 A1
(43) Pub. Date: Aug. 11, 2016

(54) CHAMBERS FOR PARTICLE REDUCTION IN SUBSTRATE PROCESSING SYSTEMS

(71) Applicant: LAM RESEARCH CORPORATION, Fremont, CA (US)

(72) Inventor: Travis R. Taylor, Fremont, CA (US)

(21) Appl. No.: 14/614,736

(22) Filed: Feb. 5, 2015

(51) Int. Cl. H01L 21/67; C23C 14/50; C23C 14/24; C23C 16/44; C23C 16/458

(52) U.S. Cl. CPC H01L 21/6719; C23C 16/4408; C23C 16/4585; C23C 14/24; C23C 14/50; H01L 21/67069; H01L 21/67201

(57) ABSTRACT

A substrate processing system includes a chamber configured to process a semiconductor substrate. At least one surface of the chamber includes a high surface area finish. A purge/vent system is configured to selectively supply purge gas over the high surface area finish of the at least one surface to trap particles in the high surface area finish without opening the chamber. The high surface area finish on the at least one surface of the chamber has a porosity within a predetermined range from 30-60%. The porosity is defined by a normalized density of the high surface area finish relative to an underlying native bulk material of the at least one surface of the chamber.

### FIELD

The present disclosure relates to substrate processing systems, and more particularly to particle reduction in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Referring now to FIG. 1, an example of a substrate processing tool 20 includes a transport handling chamber 21 and multiple reactors each with one or more substrate processing chambers. A substrate 25 enters the substrate processing tool 20 from a cassette and/or pod 23, such as a front opening unified pod (FOUP). A robot 24 includes one or more end effectors to handle the substrate 25. A pressure of the transport handling chamber 21 may be at atmospheric pressure. Alternately, the transport handling chamber 21 may be at vacuum pressure (with ports acting as isolation valves).

The robot 24 moves the substrates 25 from the cassette and/or pod to a loadlock chamber 30. For example, the substrate 25 enters the loadlock chamber 30 through a port 32 (or isolation valve) and is placed on a loadlock pedestal 33. The port 32 to the transport handling chamber 21 closes and the loadlock chamber 30 is pumped down to an appropriate pressure for transfer. Then a port 34 opens and another robot 36 (also with one or more end effectors) in a processing handling chamber 35 places the substrates through one of the ports 37-1, 37-2, 37-3 (collectively ports 37) corresponding to a selected reactor 40-1, 40-2, and 40-3 (collectively reactors 40).

A substrate indexing mechanism 42 may be used to further position the substrates relative to the substrate processing chambers. In some examples, the indexing mechanism 42 includes a spindle 44 and a transfer plate 46.

The processing chambers or stations of the reactors 40 may be capable of performing semiconductor processing operations, such as a material deposition or etching, sequentially or simultaneously with the other stations. One or more of the stations may perform semiconductor processing operations using plasma.

The substrate is moved from one station to the next in the reactor 40 using the substrate indexing mechanism 42. One or more of the stations of the reactors 40 may be capable of performing RF plasma deposition or etching. During use, the substrates are moved to one or more of the reactors 40, processed and then returned.

The substrate processing tool 20 may include one or more metrology chambers or stations 48, such as a mass metrology station. In FIG. 1, while the metrology station 48 is connected to the transport handling chamber 21, the metrology station 48 may be connected to the processing handling chamber 35. In some examples, the substrate processing tool 20 includes one or more buffer stations 49.

For example, a substrate may be received, moved to one of the reactors 40-1 for processing, moved to the metrology station 48, moved to another one of the reactors 40-2 for processing, moved to the metrology station 48, moved to another one of the reactors 40-3 for processing and then returned to the cassette.

During movement through the substrate processing tool 20, suspended particles or particles on chamber surfaces in the load lock or processing chamber may travel to the substrate being processed. The particles may be generated during processing or caused by contamination. One method for removing the particles from the chambers so that they do not contaminate the substrate involves pumping purge gas and venting (hereinafter “pump/vent method”). The pump/vent method transports the particles that are suspended and/or located on the chamber surfaces using a vacuum pump and purge gas. The pump/vent method provides limited particle improvement. However, the pump/vent method can be done at times when the substrate processing tool is idle and therefore does not impact system uptime.

Another method for removing particles from chambers involves wet cleaning, which uses clean room wipes and solvent to mechanically remove particles from the chamber. Wet cleaning requires that all processes on the substrate processing tool stop. The chambers are opened to atmosphere while the wet cleaning is performed manually. This approach impacts both uptime and cost of ownership.

For logistical purposes, the processing chambers are also cleaned when the platform goes down for wet cleaning. This allows platform wet cleaning and process chamber wet cleaning to occur in parallel. While the parallel cleaning consolidates downtime, when the platform mean wafers between cleans (MWBC) is shorter than a processing chamber module MWBC, the platform cleaning frequency determines the system uptime.

### SUMMARY

A substrate processing system includes a chamber configured to process a semiconductor substrate. At least one surface of the chamber includes a high surface area finish. A purge/vent system is configured to selectively supply purge gas over the high surface area finish of the at least one surface to trap particles in the high surface area finish without opening the chamber. The high surface area finish on the at least one surface of the chamber has a porosity within a predetermined range from 30-60%. The porosity is defined by a normalized density of the high surface area finish relative to an underlying native bulk material of the at least one surface of the chamber.

In other features, the chamber includes a processing chamber configured to treat a substrate. The chamber further includes a substrate support. The high surface area finish is arranged on the substrate support. The chamber includes a top surface, a bottom surface and side surfaces. A removable plate portion includes the high surface area finish and is arranged adjacent to at least one of the top surface, the bottom surface and the side surfaces.

In other features, the chamber includes a loadlock. The loadlock includes an upper plate and a lower plate. The high surface area finish is located on at least one of a lower surface of the upper plate and an upper surface of the lower plate. The loadlock includes an upper plate, a lower plate, and a removable plate portion arranged adjacent to one of the upper plate and the lower plate. An outer surface of the removable portion includes the high surface area finish.

A substrate processing system includes a chamber configured to process a semiconductor substrate. At least one surface of the chamber includes a high surface area finish. A purge/vent system is configured to selectively supply purge gas over the high surface area finish of the at least one surface to trap particles in the high surface area finish without opening the chamber. The high surface area finish on the at least one surface of the chamber has an average pore size in a predetermined range from 1 micrometer to 10 micrometers.

In other features, the chamber includes a processing chamber configured to treat a substrate. The chamber further includes a substrate support. The high surface area finish is arranged on the substrate support. The chamber includes a top surface, a bottom surface and side surfaces. A removable plate includes the high surface area finish and is arranged adjacent to at least one of the top surface, the bottom surface and the side surfaces. The chamber includes a loadlock. The loadlock includes an upper plate and a lower plate. The high surface area finish is located on at least one of a lower surface of the upper plate and an upper surface of the lower plate. The loadlock includes an upper plate, a lower plate and a removable plate portion arranged adjacent to one of the upper plate and the lower plate. An outer surface of the removable portion includes the high surface area finish.

A method for operating a substrate processing system includes providing at least one surface of a chamber configured to process a semiconductor substrate with a high surface area finish; and selectively supplying purge gas over the high surface area finish of the at least one surface to trap particles in the high surface area finish without opening the chamber. The high surface area finish on the at least one surface of the chamber has a porosity within a predetermined range from 30-60%. The porosity is defined by a normalized density of the high surface area finish relative to an underlying native bulk material of the at least one surface of the chamber.

In other features, the chamber includes a processing chamber configured to treat a substrate. The chamber further includes a substrate support. The method includes arranging the high surface area finish on the substrate support. The chamber includes a top surface, a bottom surface and side surfaces. The method includes providing a removable plate portion including the high surface area finish; and arranging the removable plate portion adjacent to at least one of the top surface, the bottom surface and the side surfaces.

In other features, the chamber includes a loadlock. The loadlock includes an upper plate and a lower plate. The method further includes locating the high surface area finish on at least one of a lower surface of the upper plate and an upper surface of the lower plate. The loadlock includes an upper plate, a lower plate and a removable plate portion arranged adjacent to one of the upper plate and the lower plate. The method includes locating the high surface area finish on an outer surface of the removable plate portion.

In other features, the method includes opening the chamber and removing the removable plate portion. The method includes cleaning particulates from the removable plate portion; re-installing the removable plate portion; and closing the chamber. The method includes replacing the removable plate portion with another removable plate portion.

A method for operating a substrate processing system includes providing at least one surface of a chamber configured to process a semiconductor substrate with a high surface area finish without opening the chamber; and selectively supplying purge gas over the high surface area finish of the at least one surface to trap particles in the high surface area finish. The high surface area finish on the at least one surface of the chamber has an average pore size in a predetermined range from 1 micrometer to 10 micrometers.

In other features, the chamber includes a processing chamber configured to treat a substrate. The chamber further includes a substrate support. The method further includes arranging the high surface area finish on the substrate support.

In other features, the chamber includes a top surface, a bottom surface and side surfaces. The method further includes providing a removable plate portion including the high surface area finish; and arranging the removable plate portion adjacent to at least one of the top surface, the bottom surface and the side surfaces.

In other features, the chamber includes a loadlock. The loadlock includes an upper plate and a lower plate. The method further includes locating the high surface area finish on at least one of a lower surface of the upper plate and an upper surface of the lower plate.

In other features, the loadlock includes an upper plate, a lower plate and a removable plate portion arranged adjacent to one of the upper plate and the lower plate. The method includes locating the high surface area finish on an outer surface of the removable plate portion.

In other features, the method includes opening the chamber and removing the removable plate portion. The method includes cleaning particulates from the removable plate portion; re-installing the removable plate portion; and closing the chamber. The method includes replacing the removable plate portion with another removable plate portion.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing tool according to the prior art;

FIG. 2 is a side cross-sectional view of an example of a loadlock according to the prior art;

FIG. 3 is a plan view of an example of a loadlock bottom plate according to the prior art;

FIG. 4 is a side cross-sectional view of an example of a loadlock according to the present disclosure;

FIG. 5 is a plan view of an example of a loadlock bottom plate according to the present disclosure;

FIG. 6 is a side cross-sectional view of another example of a loadlock with a removable portion including a particle trapping surface according to the present disclosure;

FIG. 7 is a functional block diagram of an example of a system for removing particles according to the present disclosure;

FIG. 8 is a flowchart illustrating steps of a method for removing particles from a processing chamber or loadlock according to the present disclosure; and

FIG. 9 is a functional block diagram of an example of a processing chamber including one or more particle trapping surfaces.

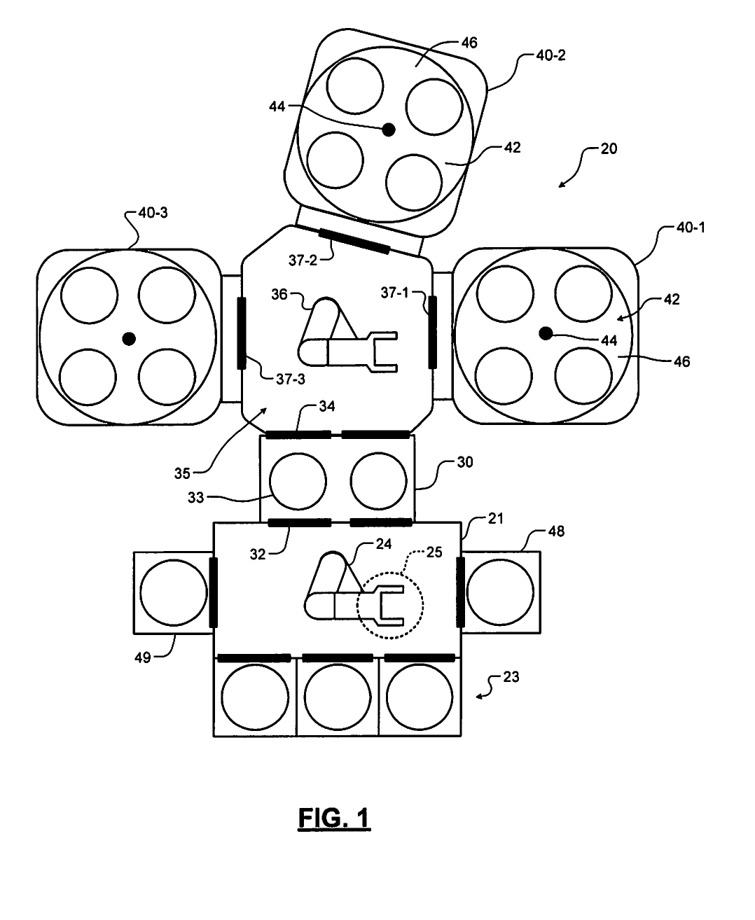

In the drawings, reference numbers may be reused to identify similar and/or identical elements.

### DETAILED DESCRIPTION

The present disclosure utilizes the pump/vent method to collide particles onto high surface area particle trapping surfaces that can trap the particles inside of the chambers. By trapping the particles in the high surface area particle trapping surfaces, the particles are prevented from travelling to the substrates being processed and defects are reduced. After a longer service interval, the high surface area particle trapping surfaces are removed, discarded and replaced, removed, cleaned and reinstalled or cleaned in situ.

In some examples, removable hardware such as a plate with the high surface area particle trapping surface is used and mounted to one or more chamber surfaces. After a longer service interval, the removable hardware is removed and replaced or removed, cleaned and reinstalled. In other words, the particle trapping surfaces are used to “clean” the chamber without requiring the chamber to be opened. As a result, MWBC may be increased.

In other examples, the particle trapping surface may be permanently integrated with one or more surfaces in the chambers and cannot be readily removed. The permanent particle trapping surfaces will require cleaning in the clean room.

In other examples, the particle trapping surface is integrated with removable components that have an existing alternative function and can be readily removed. Once removed, the particle trapping surface may be removed, cleaned and reinstalled or removed and replaced. Examples include wafer pedestals, wafer supports, and removable chamber top or bottom surfaces.

Using the systems and methods described herein will tend to decrease cost for one or more reasons. Time between cleans will be longer thereby decreasing the number of wet cleans. Furthermore, consumables in process modules may be unnecessarily replaced to maximize time between wet cleans. For example, the wet clean frequency due to the platform may be 25 k wafers and the process module consumables may have a usable lifetime of 30 k wafers. The customer typically replaces the process module consumables at the same time to ensure the entire system can go for another 25 k wafers. Otherwise the process module would have to be cleaned at 5 k wafers. In other words, 5 k wafers lifetime is lost. Fewer wet cleans translates into more time to run production (increased uptime).

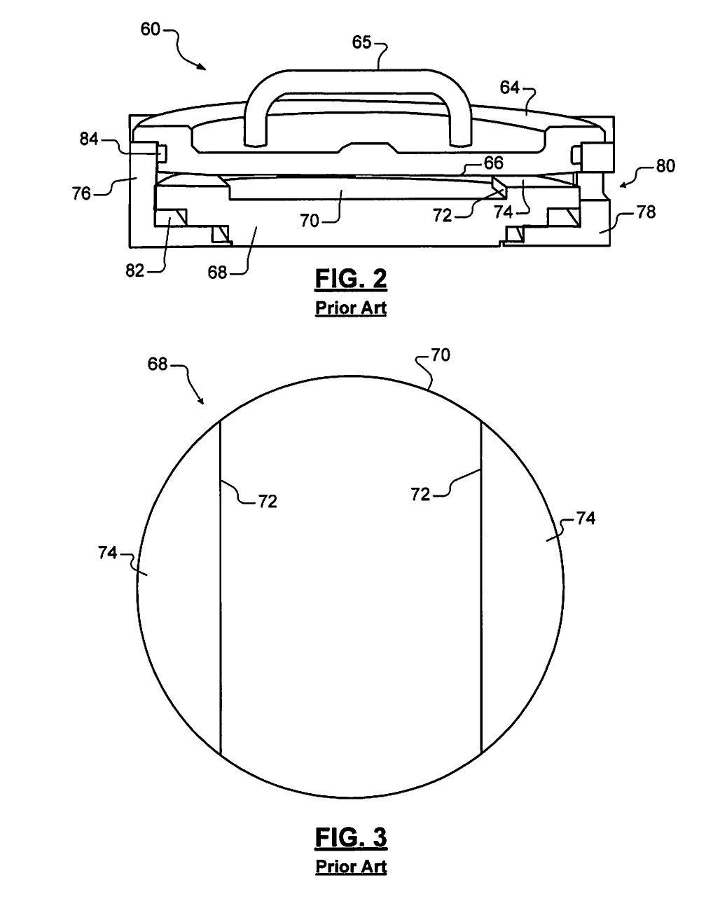

Referring now to FIGS. 2-3, an example of a loadlock 60 according to the prior art is shown. In FIG. 2, the loadlock includes an upper plate 64 having a handle 65 attached thereto and a lower surface 66. A lower plate 68 includes upper surfaces 70, 72 and 74. The upper and lower plates 64 and 68 are arranged between outer walls 76, 78 defining an opening 80. The surface 74 defines a ledge to support the substrate during use. A pump annulus 82 is provided below the lower plate 68. A vent annulus 84 is provided around the upper plate 64. In FIG. 3, a plan view of the lower surface 66 of the upper plate or an upper surface of the lower plate 68 is shown.

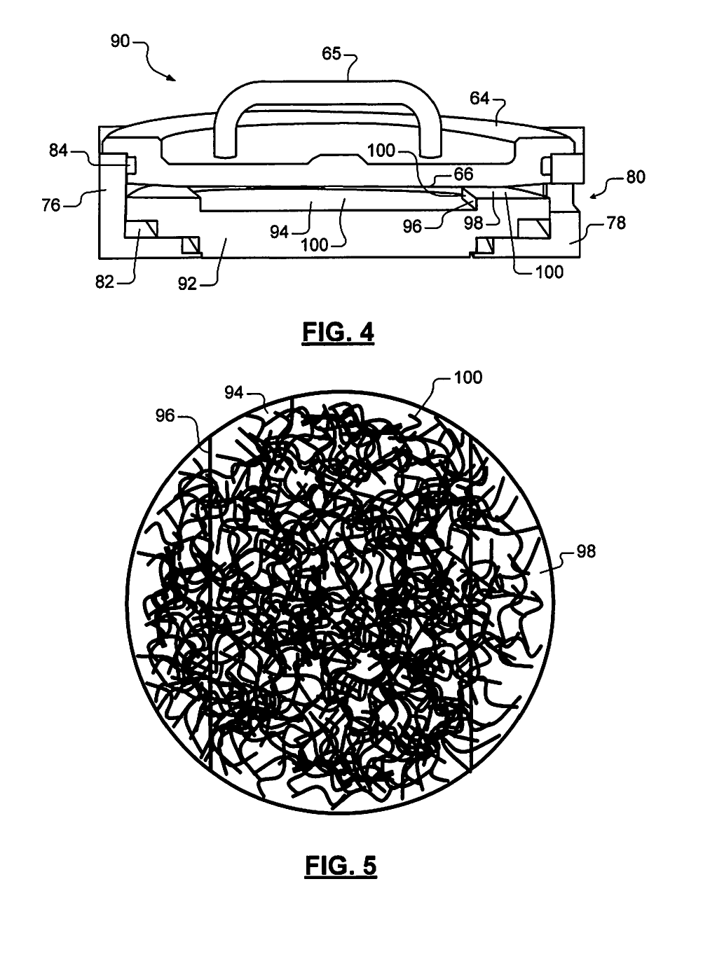

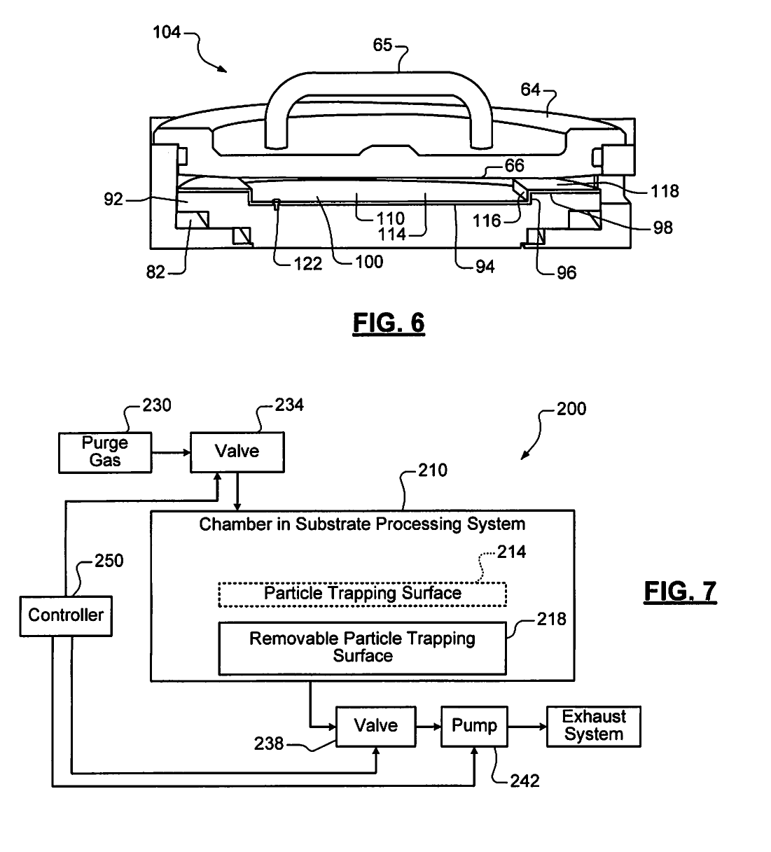

Referring now to FIGS. 4-5, an example of a loadlock 90 according to the present disclosure is shown. In FIG. 4, the loadlock 90 includes the upper plate 64 having a handle 65 attached thereto and a lower surface 66. A lower plate 92 includes upper surfaces 94, 96 and 98 facing the lower surface 66. The upper and lower plates 64 and 92, respectively are arranged between walls 76, 78 defining the opening 80. The surface 98 defines a ledge to support the substrate during transfer. A pump annulus 82 is provided around and below the lower plate 92. A vent annulus 84 is provided around the upper plate 64. In FIG. 5, a plan view of the lower plate 92 shows a high surface area finish 100 that acts as a particle trapping surface on one or more of the upper surfaces 94, 96 and 98.

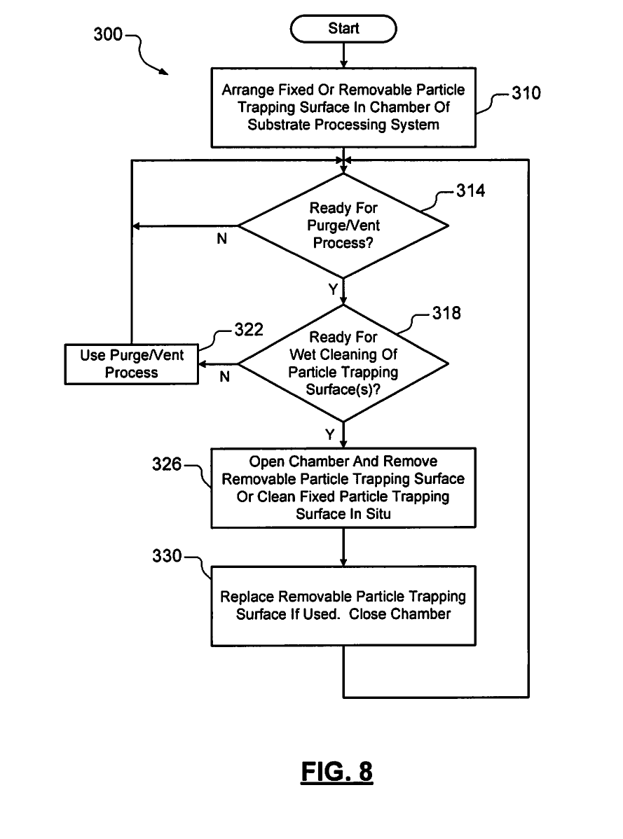

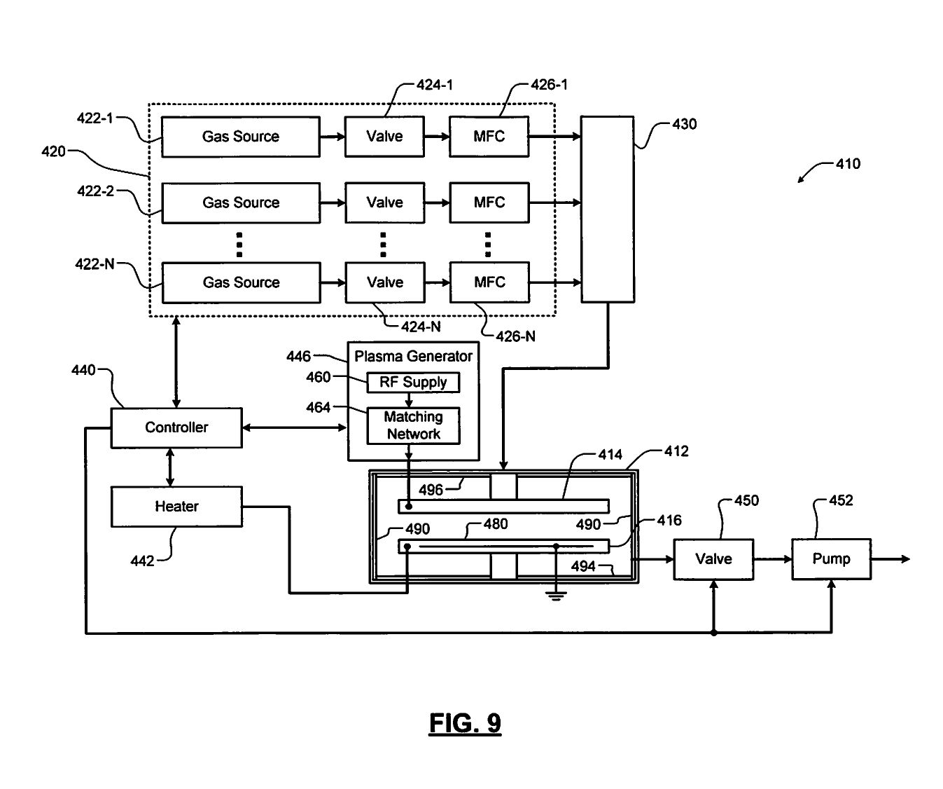

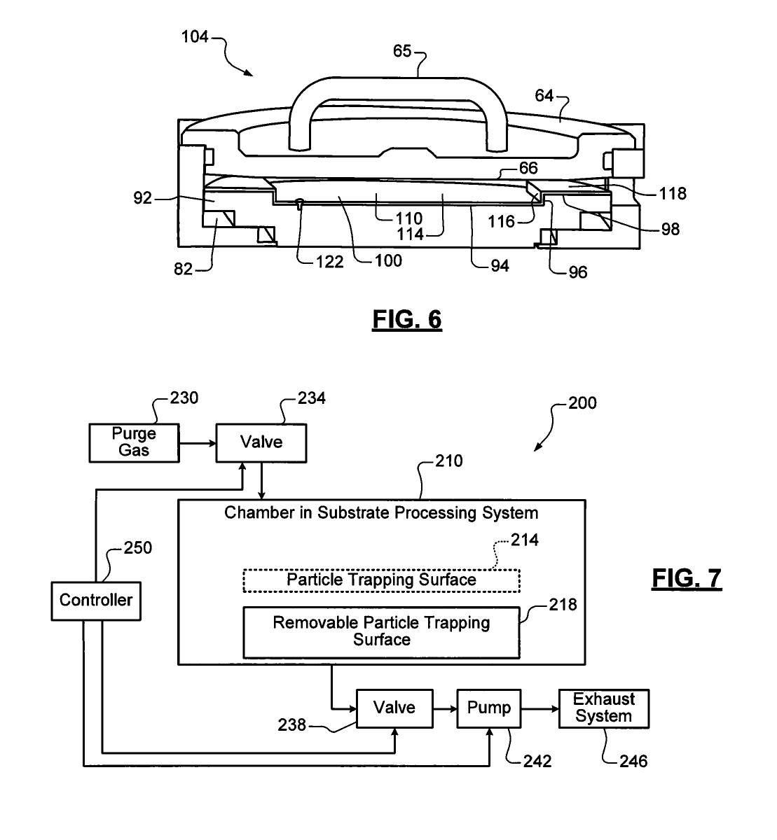

Referring now to FIG. 6, another example of a loadlock 104 is shown. In this example, a removable plate portion 114 is located adjacent to the lower plate 92. The removable plate portion 110 includes one or more surfaces 114, 116 and 118 that are generally arranged adjacent to one or more of the upper surfaces 94, 96 and 98, respectively. One or more of the surfaces 114, 116 and 118 may include the high surface area finish 100 that acts as a particle trapping surface. The removable plate portion 110 may be attached to the lower plate 92 using one or more fasteners 122. As will be described further below, a purge/vent system may be used to direct purge gas along the high surface area finish 100 on the surfaces 114, 116 and/or 118. As a result, particles are trapped and the loadlock may remain in service for a longer period before requiring maintenance.

As used herein, porosity may be used to characterize the surfaces having a high surface area finish. As used herein, porosity is defined as a normalized density relative to a native bulk material. For example only, stainless steel may be used for the chamber surface with the high surface area finish. In this example, porosity is defined by the normalized density of a stainless steel filter medium divided by the density of stainless steel. In some examples, the porosity is defined by density in a predetermined range from 30-60%. In other examples, the high surface area finish is defined by a surface with an average pore size in a range from 1-10 micrometers (μm).

Referring now to FIG. 7, a system 200 for removing particles from a loadlock or chamber is shown. The system 200 includes a loadlock or other processing chamber 210 in a substrate processing system. The loadlock or other processing chamber 210 includes a chamber surface with a fixed particle trapping surface 214 and/or a removable particle trapping surface 218. The system 200 may employ the pump/vent method to remove particles from the loadlock or other processing chamber 210. A purge gas source 230 may be supplied via a valve 234 to the chamber 210. A valve 238, a pump 242 and an exhaust system 246 may be used to vent the chamber 210. A controller 250 may communicate with the valve 234, the valve 238, and the pump 242 to control the pump/vent cycling.

Referring now to FIG. 8, a method 300 for removing particles from a chamber is shown. At 310, a chamber surface with fixed or removable particle trapping surface is arranged in a chamber of a substrate processing system. At 314, control determines whether the system is ready for a purge/vent process. If not, control returns to 314. Otherwise, control continues at 318 and determines whether the system is ready for wet cleaning of the particle trapping surface. If not, the purge/vent process is executed at 322 and control returns to 314.

The system may be ready for wet cleaning of the chamber surface with particle trapping surface after a predetermined period, a predetermined number of purge/vent cycles, or using another event. When 318 is true, the chamber is opened and the chamber surface with the removable particle trapping surface is removed or the fixed particle trapping surface is cleaned in situ at 326. At 330, if the removable particle trapping surface is used, it is cleaned and replaced (or a spare is used). When the removable particle trapping surface is replaced or the fixed particle trapping surface is cleaned, the chamber is closed. Control returns to 314.

Referring now to FIG. 9, an example of a substrate processing system 410 for removing mechanical particles using RF cycling and purging is shown. The substrate processing system 410 includes a processing chamber 412. Gas may be supplied to the processing chamber 412 using a gas distribution device 414 such as showerhead or other device. A substrate 418 such as a semiconductor wafer may be arranged on a substrate support 416 during processing. The substrate support 416 may include a pedestal, an electrostatic chuck, a mechanical chuck or other type of substrate support.

A gas delivery system 420 may include one or more gas sources 422-2, 422-2, . . . , and 422-N (collectively gas sources 422), where N is an integer greater than one. Valves 424-1, 424-2, . . . , and 424-N (collectively valves 424), mass flow controllers 426-1, 426-2, . . . , and 426-N (collectively mass flow controllers 426), or other flow control devices may be used to controllably supply precursor, reactive gases, inert gases, purge gases, and mixtures thereof to a manifold 430, which supplies the gas mixture to the processing chamber 412.

A controller 440 may be used to monitor process parameters such as temperature, pressure etc. (using sensors) and to control process timing. The controller 440 may be used to control process devices such as the gas delivery system 420, a pedestal heater 442, and/or a plasma generator 446. The controller 440 may also be used to evacuate the processing chamber 412 using a valve 450 and pump 452.

The RF plasma generator 446 generates the RF plasma in the processing chamber. The RF plasma generator 446 may be an inductive or capacitive-type RF plasma generator. In some examples, the RF plasma generator 446 may include an RF supply 460 and a matching and distribution network 464. While the RF plasma generator 446 is shown connected to the gas distribution device 414 with the pedestal grounded or floating, the RF generator 446 can be connected to the substrate support 416 and the gas distribution device 414 can be grounded or floating.

In FIG. 9, one or more particle trapping surfaces are integrated with removable components that have an existing alternative function and can be readily removed. For example only, a particle trapping surface 480 may be located on an upwardly-facing surface of the substrate support 416. Alternately, removable plate portions 490 may be arranged on side walls of the processing chamber 412 or removable plate portions 494 and 496 may be arranged on bottom or top surfaces of the processing chamber 412. The removable plate portions 490, 494 and/or 496 may include the particle trapping surfaces. As can be appreciated, the particle trapping surfaces can be integrated with existing structures or removable plate portions can be used. Fasteners or other mechanical attachments may be used to secure the removable plate portions as shown in FIG. 6.

Large particles (>500 nm) are transported with the bulk flow of the purge gas. When the purge gas flow impinges on a surface, the particle experiences an inelastic collision with the surface. The particle physically deforms and becomes part of the surface. However the motion of small particles (<100 nm) is not determined by the bulk gas flow. Rather, the small particles travel on a random walk throughout the gas (diffusion). The small particles will not have the same momentum as the large particles and therefore do not experience inelastic collision. Small particle can diffuse into a porous medium and then not find their way out. If the small particles collide with a surface, they can adhere by induced electrostatic forces (van der Waals).

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. As used herein, the phrase at least one of A, B, and C should be construed to mean a logical (A OR B OR C), using a non-exclusive logical OR, and should not be construed to mean “at least one of A, at least one of B, and at least one of C.” It should be understood that one or more steps within a method may be executed in different order (or concurrently) without altering the principles of the present disclosure.

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or loadlocks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

1. A substrate processing system, comprising:
a chamber configured to process a semiconductor substrate;
at least one surface of the chamber including a high surface area finish; and
a purge/vent system configured to selectively supply purge gas over the high surface area finish of the at least one surface to trap particles in the high surface area finish without opening the chamber,
wherein the high surface area finish on the at least one surface of the chamber has a porosity within a predetermined range from 30-60%, and
wherein the porosity is defined by a normalized density of the high surface area finish relative to an underlying native bulk material of the at least one surface of the chamber.

2. The substrate processing system of claim 1, wherein the chamber includes a processing chamber configured to treat a substrate.

3. The substrate processing system of claim 1, wherein the chamber further includes a substrate support, and wherein the high surface area finish is arranged on the substrate support.

4. The substrate processing system of claim 1, wherein the chamber includes a top surface, a bottom surface and side surfaces, and wherein a removable plate portion includes the high surface area finish and is arranged adjacent to at least one of the top surface, the bottom surface and the side surfaces.

5. The substrate processing system of claim 1, wherein the chamber includes a loadlock.

6. The substrate processing system of claim 5, wherein the loadlock includes an upper plate and a lower plate, wherein the high surface area finish is located on at least one of a lower surface of the upper plate and an upper surface of the lower plate.

7. The substrate processing system of claim 5, wherein the loadlock includes:
an upper plate;
a lower plate; and
a removable plate portion arranged adjacent to one of the upper plate and the lower plate, wherein an outer surface of the removable plate portion includes the high surface area finish.

8. A substrate processing system, comprising:
a chamber configured to process a semiconductor substrate;
at least one surface of the chamber including a high surface area finish; and
a purge/vent system configured to selectively supply purge gas over the high surface area finish of the at least one surface to trap particles in the high surface area finish without opening the chamber,
wherein the high surface area finish on the at least one surface of the chamber has an average pore size in a predetermined range from 1 micrometer to 10 micrometers.

9. The substrate processing system of claim 8, wherein the chamber includes a processing chamber configured to treat a substrate.

10. The substrate processing system of claim 8, wherein the chamber further includes a substrate support, and wherein the high surface area finish is arranged on the substrate support.

11. The substrate processing system of claim 8, wherein the chamber includes a top surface, a bottom surface and side surfaces, and wherein a removable plate includes the high surface area finish and is arranged adjacent to at least one of the top surface, the bottom surface and the side surfaces.

12. The substrate processing system of claim 8, wherein the chamber includes a loadlock.

13. The substrate processing system of claim 12, wherein the loadlock includes an upper plate and a lower plate, wherein the high surface area finish is located on at least one of a lower surface of the upper plate and an upper surface of the lower plate.

14. The substrate processing system of claim 12, wherein the loadlock includes:
an upper plate;
a lower plate; and
a removable plate portion arranged adjacent to one of the upper plate and the lower plate, wherein an outer surface of the removable plate portion includes the high surface area finish.

15. A method for operating a substrate processing system, comprising:
providing at least one surface of a chamber configured to process a semiconductor substrate with a high surface area finish; and
selectively supplying purge gas over the high surface area finish of the at least one surface to trap particles in the high surface area finish without opening the chamber,
wherein the high surface area finish on the at least one surface of the chamber has a porosity within a predetermined range from 30-60%, and
wherein the porosity is defined by a normalized density of the high surface area finish relative to an underlying native bulk material of the at least one surface of the chamber.

16. The method of claim 15, wherein the chamber includes a processing chamber configured to treat a substrate.

17. The method of claim 15, wherein the chamber further includes a substrate support, and further comprising arranging the high surface area finish on the substrate support.

18. The method of claim 15, wherein the chamber includes a top surface, a bottom surface and side surfaces, and further comprising:
providing a removable plate portion including the high surface area finish; and
arranging the removable plate portion adjacent to at least one of the top surface, the bottom surface and the side surfaces.

19. The method of claim 15, wherein the chamber includes a loadlock.

20. The method of claim 19, wherein the loadlock includes an upper plate and a lower plate, and further comprising locating the high surface area finish on at least one of a lower surface of the upper plate and an upper surface of the lower plate.

21. The method of claim 19, wherein the loadlock includes an upper plate, a lower plate and a removable plate portion arranged adjacent to one of the upper plate and the lower plate, and further comprising locating the high surface area finish on an outer surface of the removable plate portion.

22. The method of claim 21 further comprising:
opening the chamber; and
removing the removable plate portion.

23. The method of claim 22, further comprising:
cleaning particulates from the removable plate portion;
re-installing the removable plate portion; and
closing the chamber.

24. The method of claim 22, further comprising:
replacing the removable plate portion with another removable plate portion; and
closing the chamber.

25. A method for operating a substrate processing system, comprising:
providing at least one surface of a chamber configured to process a semiconductor substrate with a high surface area finish without opening the chamber; and
selectively supplying purge gas over the high surface area finish of the at least one surface to trap particles in the high surface area finish,
wherein the high surface area finish on the at least one surface of the chamber has an average pore size in a predetermined range from 1 micrometer to 10 micrometers.

26. The method of claim 25, wherein the chamber includes a processing chamber configured to treat a substrate.

27. The method of claim 25, wherein the chamber further includes a substrate support, and further comprising arranging the high surface area finish on the substrate support.

28. The method of claim 25, wherein the chamber includes a top surface, a bottom surface and side surfaces, and further comprising:
providing a removable plate portion including the high surface area finish; and
arranging the removable plate portion adjacent to at least one of the top surface, the bottom surface and the side surfaces.

29. The method of claim 25, wherein the chamber includes a loadlock.

30. The method of claim 29, wherein the loadlock includes an upper plate and a lower plate, and further comprising locating the high surface area finish on at least one of a lower surface of the upper plate and an upper surface of the lower plate.

31. The method of claim 30, wherein the loadlock includes an upper plate, a lower plate and a removable plate portion arranged adjacent to one of the upper plate and the lower plate, and further comprising locating the high surface area finish on an outer surface of the removable plate portion.

32. The method of claim 31, further comprising:
opening the chamber; and
removing the removable plate portion.

33. The method of claim 32, further comprising:
cleaning particulates from the removable plate portion;
re-installing the removable plate portion; and
closing the chamber.

34. The method of claim 32, further comprising:
replacing the removable plate portion with another removable plate portion; and
closing the chamber.
